(19) United States
(12) Patent Application Publication
(10) Pub. No.: US 2015/0171261 A1
(43) Pub. Date: Jun. 18, 2015

(54) TRANSPARENT CONDUCTIVE OXIDE (TCO) LAYER, AND SYSTEMS, APPARATUSES AND METHODS FOR FABRICATING A TRANSPARENT CONDUCTIVE OXIDE (TCO) LAYER

(71) Applicant: Tel Solar AG, Trubbach (CH)

(72) Inventor: Didier DOMINE, Trubbach (CH)

(73) Assignee: Tel Solar AG, Trubbach (CH)

(21) Appl. No.: 14/109,562

(22) Filed: Dec. 17, 2013

(51) Int. Cl. H01L 31/18; H01L 31/0224

(52) U.S. Cl. CPC H01L 31/1888; H01L 31/022483; H01L 31/022433

(57) ABSTRACT

A transparent conductive oxide (TCO) layer formed using a post-TCO layer deposition process to increase roughness, aspect ratio and/or peak-to-valley heights of the surface topography relative to as-grown surface topography, and systems, apparatuses and methods thereof. A TCO layer is provided or formed with an as-grown surface topography, and processes are performed to the as-grown surface topography to modify the surface topography to increase roughness, aspect ratio, and/or peak-to-valley heights. The increase in roughness, aspect ratio, and/or peak-to-valley heights of surface topography is performed by at least one of increasing the heights of the peaks and increasing the depths of the valleys. The increase in roughness, aspect ratio, and/or peak-to-valley heights of surface topography can be to a desired or predetermined roughness and/or aspect ratio or an amount of increase in aspect ratio.

### BACKGROUND

1. Technical Field

Embodiments disclosed herein, generally speaking, relate to forming a portion or portions of a photovoltaic (PV) device, and more particularly to forming a transparent conductive oxide (TCO) layer of a PV device. Of course, transparent conductive oxide layers according to embodiments of the present invention can also be implemented in other optoelectronic devices, such as Organic Light-Emitting Diodes (OLEDs).

2. Background

Photovoltaic devices, or solar cells, are devices which convert light into electrical power. Thin-film solar cells nowadays are of a particular importance since they have a potential for mass production at relatively low cost. Typically, a thin-film solar cell includes an amorphous and/or microcrystalline silicon film having a PIN (or NIP) junction structure arranged in parallel to the thin-film surface and sandwiched between transparent film electrodes.

Thin-film solar cells are typically combined in panels or modules to provide a device having desired power output, for example. A method for manufacturing thin-film solar modules provides a stack on a substrate of glass or other suitable material. The stack generally includes a first electrode (front electrode), a semiconductor layer and a second electrode (back electrode) sequentially formed on the substrate. Each of these layers is typically formed by a multi-step production process which may include forming multiple layers.

### SUMMARY

One object of embodiments of the invention is to provide a desired shape for a transparent conductive oxide (TCO) film. As will be discussed in more detail below, such desired shape is in the form of surface topography of the TCO film and can provide for improved or efficient in-coupling or trapping of light, for example, at a relatively large angle of diffraction, and efficient light scattering at a TCO-substrate interface. Additionally, a gain in short-circuit current can be achieved (e.g., in a solar cell), as well as high optical transparency and good electrical conductivity. As used herein (including in the claims and the drawings), the term “providing” can include providing or supplying a TCO film with a particular surface topography or other ways of providing a TCO film, such as making, fabricating, or forming the TCO film in one or more steps or processes, or modifying or forming the surface topography of the TCO film in one or more steps or processes.

The aforementioned objects and advantages can be realized by embodiments of the invention disclosed herein.

In general, embodiments of the present invention create or form a TCO layer with an increased roughness, aspect ratio and/or peak-to-valley heights of the surface topography relative to the TCO layer's as-grown surface topography, and the increase in roughness, aspect ratio, and/or peak-to-valley heights of surface topography can be to a desired or predetermined roughness or aspect ratio or an amount of increase in aspect ratio.

For example, one non-limiting embodiment of the present invention provides a method for fabricating a TCO layer. The method can comprise providing a first transparent ZnO layer, where the first ZnO layer is an as-grown, randomly pyramidal textured ZnO layer having a first pyramidal topography with a first roughness and a first aspect ratio; and modifying the first pyramidal topography to create a second pyramidal topography with a second roughness greater than the first roughness and with a second aspect ratio greater than the first aspect ratio.

As another example, a non-limiting embodiment of the present invention provides a method and/or apparatus for fabricating a precursor for a thin-film silicon solar cell. The method can comprise providing, in a processing chamber of fabrication equipment, a thin-film silicon layer; depositing, using the processing chamber of the fabrication equipment, a first transparent ZnO layer on the thin-film silicon layer to form an Si—ZnO interface, where the first ZnO layer is an as-grown, randomly pyramidal textured ZnO layer having a first pyramidal topography with a first roughness; and modifying, using the fabrication equipment, the first pyramidal topography to create a second pyramidal topography with a second roughness greater than the first roughness, where the modifying of the first pyramidal topography to create the second pyramidal topography includes increasing at least one of respective heights of the peaks and respective depths of the valleys of the first pyramidal topography.

Embodiments of the present invention can also include a precursor for a thin-film silicon solar cell. The precursor can comprise a TCO layer comprised of or comprised essentially of ZnO chemically deposited on a thin-film silicon layer to form an Si—ZnO interface, where the TCO layer has a roughness on a first side thereof greater than an as-grown roughness on said first side. Optionally, the TCO layer can be comprised of one or more layers of ZnO. Further, the TCO layer can have a modified surface texture, whereby the surface texture has been modified from its as-grown, randomly pyramidal textured ZnO layer having a first pyramidal topography with a first roughness and a first aspect ratio to a resultant second pyramidal topography having a second roughness and a second aspect ratio greater than the first roughness and first aspect ratio. Optionally, the thin-film silicon layer is on a second side opposite the first side of the TCO layer. Optionally, the precursor also comprises a glass substrate over the first, as-grown side of the TCO layer, and a back electrode, where the TCO layer constitutes a front electrode.

### BRIEF DESCRIPTION OF THE DRAWINGS

The accompanying drawings, which are incorporated in and constitute a part of the specification, illustrate one or more embodiments and, together with the description, explain these embodiments. The accompanying drawings have not necessarily been drawn to scale. Any values or dimensions illustrated in the accompanying graphs and figures are for illustration purposes only and may or may not represent actual or preferred values or dimensions. Where applicable, some or all features may not be illustrated to assist in the description of underlying features. In the drawings:

FIG. 1 is a flow chart of a method according to one or more embodiments of the present invention.

FIG. 2 is a flow chart of a method according to one or more embodiments of the present invention.

FIG. 3 is a flow chart of a method according to another embodiment of the present invention.

FIGS. 4-9 are diagrammatic illustrations of a TCO layer associated with the method of FIG. 3.

FIG. 10 is a flow chart of a method according to yet another embodiment of the present invention.

FIGS. 11-14 are diagrammatic illustrations of a TCO layer associated with the method of FIG. 10.

FIG. 15 is a flow chart of a method according to another embodiment of the present invention.

FIGS. 16-20 are diagrammatic illustrations of a TCO layer associated with the method of FIG. 15.

FIG. 21 illustrates an example of a portion of a thin-film solar cell according to embodiments of the present invention.

### DESCRIPTION OF EMBODIMENTS

The description set forth below in connection with the appended drawings is intended as a description of various embodiments of the invention and is not necessarily intended to represent the only embodiment or embodiments in which the invention may be practiced. In certain instances, the description includes specific details for the purpose of providing an understanding of the invention. However, it will be apparent to those skilled in the art that the invention may be practiced without these specific details. In some instances, some structures and components may be shown in block diagram form in order to avoid obscuring the concepts of the disclosed subject matter.

Additionally, reference throughout the specification to “one embodiment” or “an embodiment” means that a particular feature, structure, or characteristic described in connection with an embodiment is included in at least one embodiment of the subject matter disclosed. Thus, any appearance of the phrases “in one embodiment” or “in an embodiment” in the specification is not necessarily referring to the same embodiment. Further, the particular features, structures or characteristics may be combined in any suitable manner in one or more embodiments. Additionally, it must be noted that, as used in the specification and the appended claims, the singular forms “a,” “an,” and “the” include plural referents unless the context clearly dictates otherwise. That is, unless clearly specified otherwise, as used herein the words “a” and “an” and the like carry the meaning of “one or more.” Further, it is intended that the present invention and embodiments thereof cover the modifications and variations. For example, it is to be understood that terms such as “left,” “right,” “top,” “bottom,” “front,” “rear,” “side,” “height,” “length,” “width,” “upper,” “lower,” “interior,” “exterior,” “inner,” “outer,” and the like that may be used herein, merely describe points of reference and do not limit the present invention to any particular orientation or configuration. Furthermore, any use of terms such as “first,” “second,” “third,” etc., merely identifies one of a number of portions, components and/or points of reference as disclosed herein, and likewise do not limit the present invention to any particular configuration, orientation, number, or order.

The following definitions are provided to facilitate understanding of the description provided herein:

Processing in the sense of this invention can include any chemical, physical or mechanical effect acting on substrate(s), layer(s), or layer portion(s).

Substrates in the sense of this invention can include components, parts or workpieces to be treated in a processing apparatus. Substrates include, but are not limited to flat, plate-shaped parts having rectangular, square or circular shape.

A vacuum processing or vacuum treatment system, apparatus or equipment can comprise at least an enclosure for substrates to be treated under pressures lower than ambient atmospheric pressure.

Chemical Vapor Deposition (CVD) is a technology to deposit a layer or layers on substrates, for example, heated substrates. A usually liquid or gaseous precursor material is fed to a process system where a thermal reaction of said precursor results in deposition of said layer(s). LPCVD is a common term for low pressure CVD.

TCO stands for transparent conductive oxide, TCO layers consequently are transparent conductive layers.

The terms layer, coating, deposit and film may be interchangeably used in this disclosure for a film deposited in vacuum processing equipment, be it CVD, LPCVD, plasma enhanced CVD (PECVD) or PVD (physical vapor deposition).

DEZ—diethyl zinc is a precursor material for the production of TCO layers in vacuum processing equipment.

A solar cell or photovoltaic cell (PV cell) is an electrical component, capable of transforming light (essentially sun light) directly into electrical energy by means of the photovoltaic effect.

A thin-film silicon solar cell in a generic sense includes, on a supporting substrate, at least one p-i-n junction established by a thin-film deposition of semiconductor compounds, sandwiched between two electrodes or electrode layers. A p-i-n junction or thin-film photoelectric conversion unit includes an intrinsic semiconductor compound layer sandwiched between a p-doped and an n-doped semiconductor compound layer. The term thin-film indicates that the layers mentioned are being deposited as thin layers or films by processes like, PEVCD, CVD, PVD or the like. Thin layers essentially mean layers with a thickness of 10 μm or less, especially less than 2 μm.

Diborane—Technically B₂H₆ (boron dopant) is available as a gas mixture of 2% B₂H₆ in hydrogen.

Haze is defined as the ratio of transmitted scattered light to the total transmitted light. Haze can be measured using a spectro-photometer equipped with an integrating sphere. For example, haze may refer to haze at a wavelength of 600 nm.

Generally speaking, embodiments of the present invention are directed to a transparent conductive oxide (TCO) film or layer having a desired or optimal shape and methods, apparatuses, and systems for providing or making such TCO film or layer. As used herein, the term film or layer can include more than layer or film portions. Thus, for example, a TCO film or layer comprised of or consisting of a first TCO layer and a second TCO layer may be referred to as a TCO layer.

As noted above, TCO films according to embodiments of the present invention may be implemented as part of a thin-film silicon solar cell, for example, as a front electrode or contact. Of course, embodiments of the present invention are not so limited, and TCO films according to embodiments of the present invention may be used in other implementations, such as display or lighting devices. Additionally, embodiments of the present invention can be used to form or create a master mold or die with surface topographies as illustrated and described herein for nano-inprinting or nano-molding.

The desired or optimal shape is in the form of surface topography of the TCO film and can provide for improved or efficient in-coupling or light trapping of light, for example at a relatively large angle of diffraction, and efficient light scattering at a TCO-substrate interface, such as a Zinc oxide-silicon interface (i.e., ZnO—Si). Additionally, a gain in short-circuit current can be achieved for a solar cell. Generally speaking, efficient light-trapping at a TCO-substrate interface for a front contact of a high efficiency thin-film silicon solar cell is important, for example, because of reduced thickness of the photoactive silicon layers in such a device. Incidentally, though a ZnO layer (e.g., a ZnO layer lightly or heavily doped with a Boron dopant) will be primarily discussed herein as the TCO layer, other TCO layers may be implemented, such as an APCVD fluorine doped tin oxide (FTO) layer (i.e., as-grown rough FTO).

Regarding ZnO layers, for instance, formed by LPCVD, such as-grown layers, generally speaking, have relatively low absorption in the visible wavelength range and can have relatively rough, randomly textured surface features (i.e., surface topography). In particular, such as-grown ZnO layers can have a random pyramidal morphology comprised of a plurality of peaks and valleys. For example, the random pyramidal morphology may have a maximum peak-to-valley height of up to 300 nm. As another example, the random pyramidal morphology may have a root mean square (rms) roughness of 200 nm and/or a correlation length of 400 nm. As-grown ZnO or FTO layers, however, may not exhibit suitable depth features for efficient light-trapping or light in-coupling, for example.

Thus, embodiments of the present invention involve forming or otherwise providing a transparent conductive oxide (TCO) layer formed using a post-TCO layer deposition process to statistically increase roughness, aspect ratio and/or peak-to-valley heights of the surface topography relative to the as-grown surface topography, and systems, apparatuses and methods thereof. Generally speaking, a TCO layer is provided or formed with an as-grown surface topography, as discussed above, and processes are performed to the as-grown surface topography to modify the surface topography to increase roughness, aspect ratio, and/or peak-to-valley heights. The increase in roughness, aspect ratio, or peak-to-valley heights of surface topography is performed by at least one of increasing the heights of the peaks and increasing the depths of the valleys. The increase in roughness, aspect ratio, or peak-to-valley heights of surface topography can be to a desired or predetermined roughness or aspect ratio or an amount of increase in aspect ratio relative to the as-grown aspect ratio.

Non-limiting examples of ranges and amounts of lateral size (i.e., quasi-pitch or self-correlation length) of the resultant TCO surface can be at or about 100 nm to at or about 1 μm, at or about 100 nm to at or about 200 nm, or at or about 175 nm. Non-limiting examples of depth or height (e.g., maximum peak-to-valley height) are at or about 200 nm to at or about 500 nm or at or about 300 nm. Thus, in one example, a resultant TCO layer in the form of a ZnO layer according to embodiments of the present invention can have a lateral size of at or about 175 nm and depth or height of at or about 300 nm. Further, in embodiments of the present invention, the aspect ratio of the resultant TCO layer can be increased by a factor of at or about 2 or at or about 1.71, for example, in the case of treatment of an as-grown ZnO layer.

Exemplary techniques for post-processing as-grown LPCVD ZnO, for example, are discussed below and may be generically referred to as (1) a selective lift-off of ZnO in valleys technique, (2) a selective etching of ZnO with masking using microcrystalline silicon (μc-Si) technique, and (3) a selective B₂H₆ exposure with masking using microcrystalline silicon (μc-Si) followed by etching (multiple times) technique.

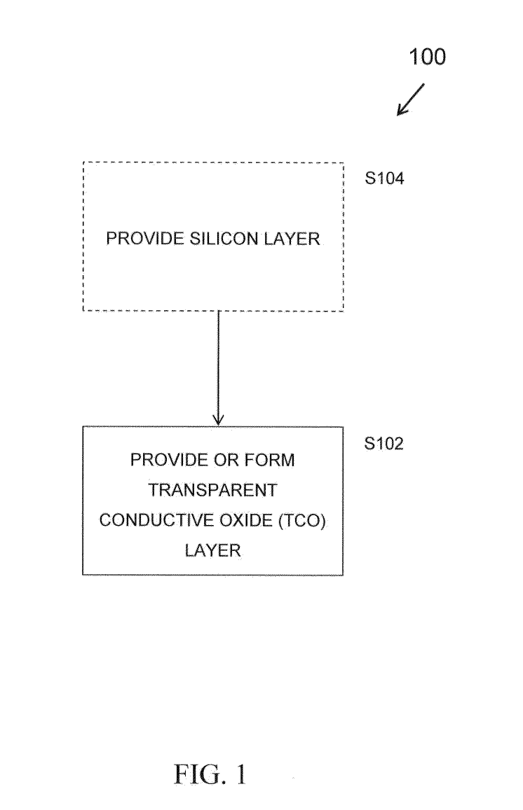

Turning to FIG. 1, FIG. 1 is a flow chart of a method 100 according to one or more embodiments of the present invention. Method 100 can include a step or process S102 of providing or forming a transparent conductive oxide (TCO) layer, such as a ZnO layer. The TCO layer can have a surface topography with a desired roughness, aspect ratio, or peak-to-valley heights, for example, to provide for improved or efficient in-coupling or trapping of light, and efficient light scattering at a Zn—Si interface, for example. The formed TCO layer can be a layer resulting from a post-deposition process initially forming the TCO layer (or a base portion thereof) and thus can increase (e.g., statistically) roughness, aspect ratio and/or peak-to-valley heights of the surface topography relative to its as-deposited surface topography.

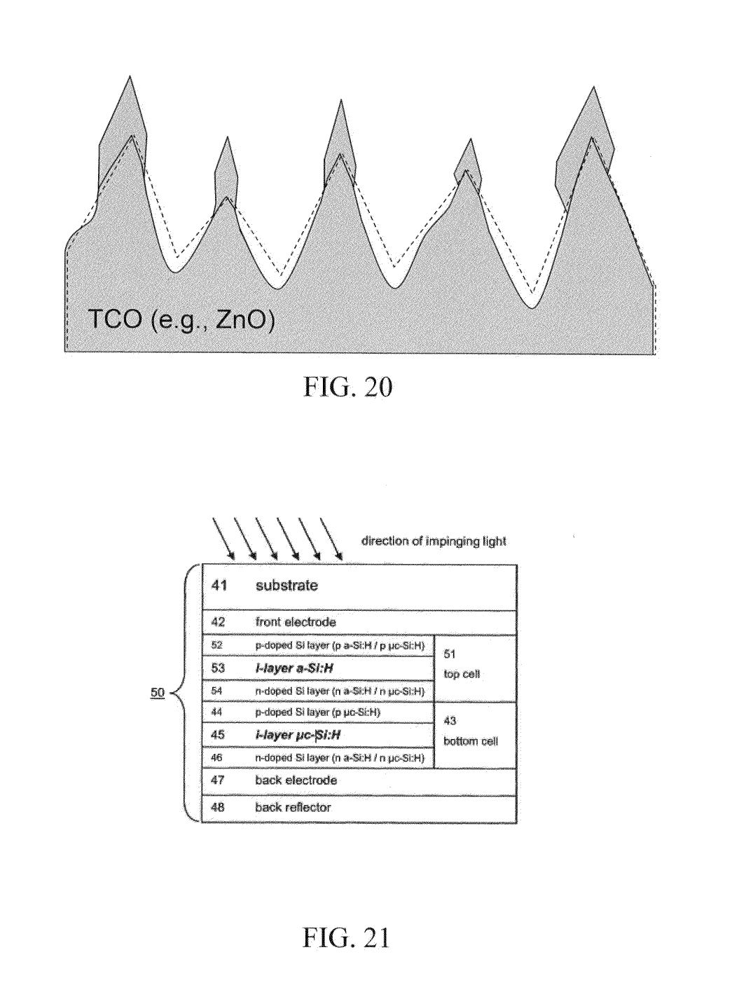

Method 100 can optionally include a step or process S104 of providing a substrate layer, such as a silicon layer (e.g., thin-film silicon layer or amorphous silicon layer). Thus, S102 can include providing or forming the TCO layer on the silicon layer. For example, a ZnO layer may be deposited on a silicon layer as part of step S102, for example, by LPCVD, and step S102 can further be comprised of processes to such ZnO layer to modify the surface topography of the deposited ZnO layer to form a resultant ZnO layer with a desired roughness, aspect ratio, or peak-to-valley heights according to embodiments of the present invention. Thus, the resultant TCO layer, described previously with respect to a resultant ZnO layer, and optionally combined with the substrate layer (e.g., a silicon layer), can form a precursor to a thin-film silicon solar cell, as well as a portion of the thin-film silicon solar cell. As will be discussed with respect to FIG. 21, other layers may also be included as part of the thin-film silicon solar cell or precursor thereto.

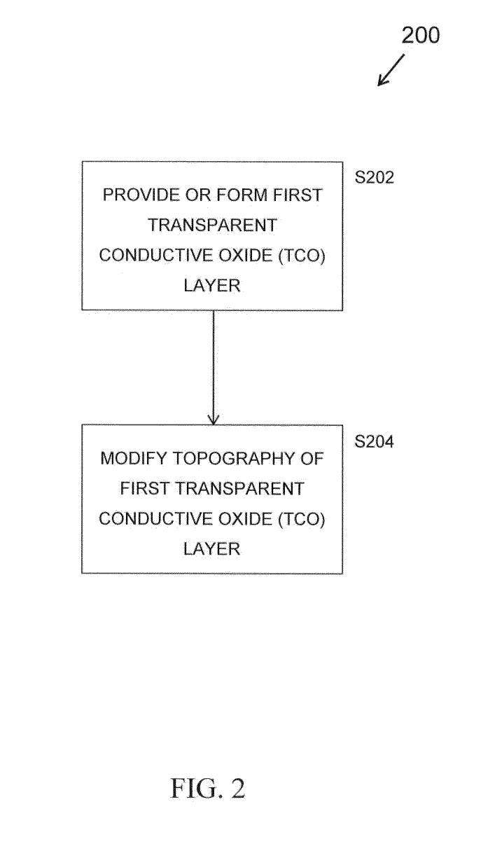

FIG. 21 illustrates a non-limiting example of a portion 50 of a thin-film silicon solar cell within which resultant TCO layers and/or precursors according to embodiments of the present invention can be implemented or form a part of the thin-film silicon solar cell, such as described and illustrated with respect to method 100 of FIG. 1, as well as the methods associated with FIGS. 2, 3, 10, and 15, which will be described in more detail below.

More particularly regarding FIG. 21, this figure illustrates a portion of a tandem junction silicon thin-film solar cell in accordance with embodiments of the invention. Such a thin-film solar cell portion 50 can include a first or front electrode 42, one or more semiconductor thin-film p-i-n junctions (52-54, 51, 44-46, 43), and a second or back electrode 47, which are successively stacked on a substrate 41. Each p-i-n junction 51, 43 or thin-film photoelectric conversion unit can include an i-type layer 53, 45 sandwiched between a p-type layer 52, 44 and an n-type layer 54, 46 (i-type=substantially intrinsic, p-type=with positive majority carriers, i.e., doped with acceptor atoms, n-type=with negative majority carriers, i.e., doped with donors). Substantially intrinsic in this context is understood as not intentionally doped or exhibiting essentially no resultant doping. Photoelectric conversion occurs primarily in this i-type layer, which is why it may also be called absorber layer.

Depending on the crystalline fraction (i.e., crystallinity) of the i-type layer 53, 45 solar cells or photoelectric (conversion) devices may be characterized as amorphous (a-Si or α-Si, 53) or microcrystalline (mc-Si or μc-Si, 45) solar cells, independent of the kind of crystallinity of the adjacent p and n-layers. Microcrystalline layers are understood as layers comprising a significant fraction of crystalline silicon—so-called micro-crystallites—in an amorphous matrix. Stacks of p-i-n junctions are called tandem or triple junction photovoltaic cells. The combination of an amorphous and micro-crystalline p-i-n-junction, as shown in FIG. 21, is also called micro-morph tandem cell.

Generally speaking, the production of thin-film silicon modules involves a number of processes or steps. For example, a transparent conductive oxide (TCO) layer can be applied as front electrode 42 on a glass substrate 41 (or comparable materials) and a silicon layer (e.g., 52) can be formed on front electrode 42. Further, in the case of tandem solar cells based on a-Si:H and μc-Si:H, the TCO, which may be FTO or ZnO, can be deposited as a front contact. Optionally, the TCO layer may be doped, for example, with Dibrorane/DEZ≈0.05). ZnO can be produced by sputtering or by LPCVD. In the case of LPCVD, layers of LPCVD ZnO, for example, are constituted of several pyramidal structures with size ranging from a few nm to several 100 nm. That is, a LPCVD ZnO layer (e.g., having a thickness of 1 μm to 4 μm or 1.6 μm to 3 μm, such as 1.9 μm) is generally rough and in the form of random pyramidal structures having peaks and valleys.

The performance of thin-film silicon cells and modules is strongly influenced by the properties of the first TCO layer(s) (front contact 42, FIG. 21). Relevant properties of the TCO to be considered are total transmission, haze, angular distribution of scattered light and conductivity. Incidentally, surface roughness (or surface texture) can cause light scattering, and one method to measure light scattering is to measure haze. In forming TCO based on LPCVD of ZnO the foregoing parameters can be varied by modifying the amount of dopant gas (e.g., Diborane, i.e., B₂H₆) added to precursor gases during growth in a LPCVD process.

Turning to FIG. 2, this figure is a flow chart of a method 200 according to one or more embodiments of the present invention. Optionally, method 200 can represent or be part of process S102 in method 100 illustrated in FIG. 1.

Method 200 can include a step or process S202 (which may involve multiple sub-steps or sub-processes) of providing or forming a transparent conductive oxide (TCO) layer, such as a ZnO layer. The TCO layer can be formed or otherwise provided by a LPCVD process, for instance. The TCO layer may be in the form of an as-grown ZnO layer, and such as-grown layer may have a surface topography in the form of randomized pyramidal structures with peaks of valleys of varying size, heights, and/or depths.

Method 200 can also include a step or process S204 (which itself may involve multiple sub-steps or sub-processes) of modifying the topography of the TCO layer. Generally speaking, S204 can create a TCO layer resulting from a post-deposition process initially forming the TCO layer (or a base portion thereof) and thus can increase (e.g., statistically) roughness, aspect ratio or peak-to-valley heights of the surface topography relative to its as-deposited surface topography. That is, S204 can modify the initial (e.g., as-grown) surface topography to increase roughness, aspect ratio, or peak-to-valley heights. Such increase in roughness, aspect ratio, or peak-to-valley heights of surface topography is performed by at least one of increasing the heights of the peaks and increasing the depths of the valleys. Increase in roughness, aspect ratio, or peak-to-valley heights of surface topography can be to a desired or predetermined roughness or aspect ratio or an amount of increase in aspect ratio relative to the as-grown aspect ratio. Non-limiting examples of ranges and amounts of lateral size (i.e., quasi-pitch or self-correlation length) of the resultant TCO surface can be at or about 100 nm to at or about 1 μm, at or about 100 nm to at or about 200 nm, or at or about 175 nm. Non-limiting examples of depth or height (e.g., maximum peak-to-valley height) are at or about 200 nm to at or about 500 nm or at or about 300 nm. As an example regarding aspect ratio, the aspect ratio of the resultant TCO layer can be increased by a factor of at or about 2 or at or about 1.71, for example, in the case of modifying the ZnO layer.

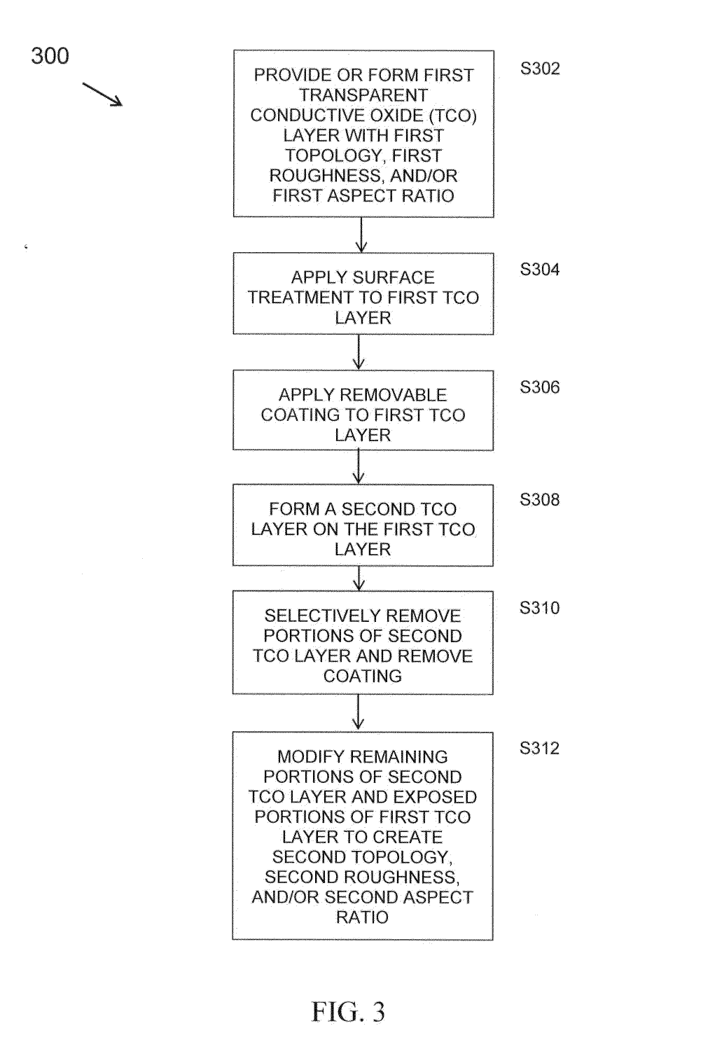

Turning to FIGS. 3-9, FIG. 3 represents a flow chart of a method 300 according to embodiments of the present invention. Generally speaking, method 300 can produce a TCO layer, such as ZnO, with a surface topography having an increased roughness, aspect ratio, or peak-to-valley heights of surface topography of a desired or predetermined roughness or aspect ratio or an amount of increase in aspect ratio relative to the as-grown aspect ratio with respect to an initial (e.g., as-grown) state of such surface topography. Method 300 may be referred to generally as a method to provide or fabricate a TCO layer having a surface topography with a desired surface roughness by selective lift-off of the TCO (e.g., ZnO) in valleys of an initial state (e.g., as-grown) state of the TCO. Further, method 300 can include, generally speaking, modifying a first pyramidal topography to create the second pyramidal topography by increasing both of respective heights of the peaks and respective depths of the valleys of the first pyramidal topography.

Method 300 can be comprised of a step or process S302 (which may involve multiple sub-steps or sub-processes), which includes providing or forming a transparent conductive oxide (TCO) layer, such as a ZnO layer. The TCO layer can be formed or otherwise provided by a LPCVD process, for instance. The TCO layer may be in the form of an as-grown ZnO layer, and such as-grown layer may have a surface topography in the form of randomized pyramidal structures with peaks of valleys of varying size, heights, and/or depths.

Method 300 may also be comprised of a step or process 5304 of applying a surface treatment to the initial TCO layer. Examples of the surface treatment include cleaning Ar plasma, surface-modifying Ar plasma (ArO₂ plasma, i.e., a mixture of Ar and O₂), CH₄ plasma, wet etch in CH₃COOH, or wet etch in methanol treatments. Such surface treatment in S304 provided for a later step or process of growing additional TCO layer(s)/layer portions on the initial TCO layer. Method 300 can also include a step or process S306 of applying a coating to the initial TCO layer. Examples of suitable coatings include a sacrificial ink, an anti-wetting mixture, sol-gel, or a photo-resist and/or anti-reflective coating. Further, such coating can be provided in a spin or slit coating process, using a corresponding coating machine or apparatus, for instance. Additionally, the amount of coating used can be such that after the coating process the coating lays only in the valleys or recess portions of the rough surface topography. FIG. 4 provides, diagrammatically, an illustration of a resultant cross-section of the initial surface topography based on processes S304 and S306. In particular, FIG. 4 illustrates that the surface treatment of S304 is a surface treatment of clean Argon (represented by the down-going arrows), and the coating process of S306 is represented by the coating C. Notably, the coating C is illustrated as being only in the valleys (and not on or over the peaks) of the randomly pyramidal topography. Additionally, though FIG. 3 indicates a particular order for processes S304 and S306, these processes may be reversed in order.

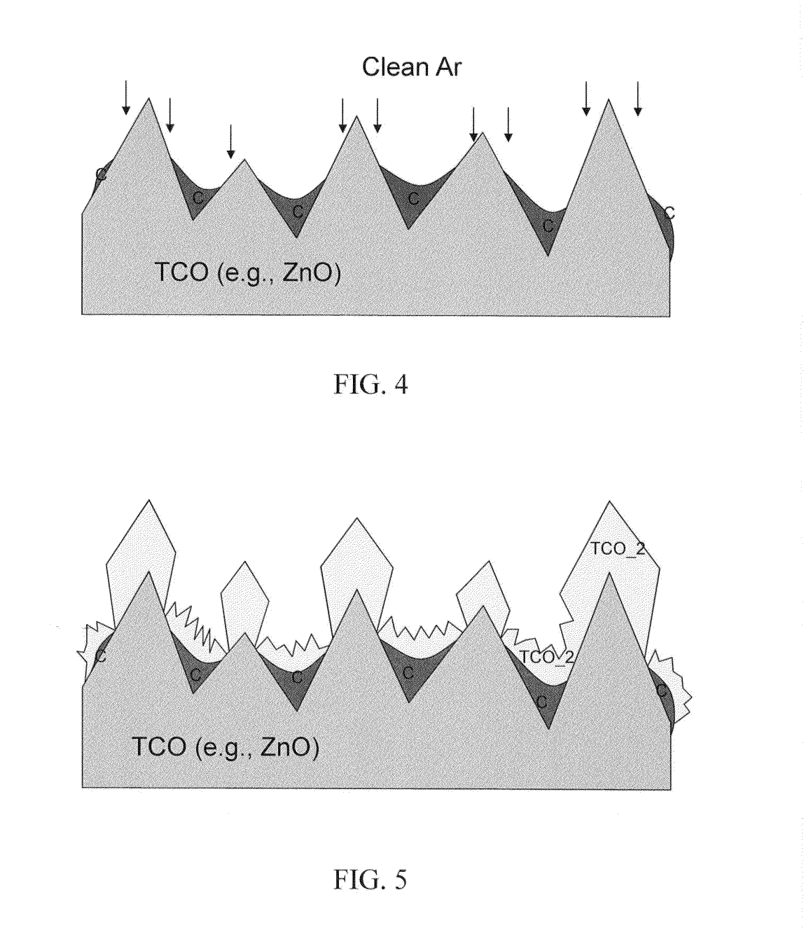

Method 300 can also include a process S308 of forming a transparent TCO layer or layer portions TCO_{—}2 on the initial TCO layer subjected to the surface treatment of S304 and with the coating C in the valleys according to process S306. For example, process S308 can form another ZnO layer TCO_{—}2 via deposition (e.g., via LPCVD) on an initial, as-grown ZnO layer subjected to the surface treatment of S304 and with the coating C in the valleys according to process S306. The second TCO layer TCO_{—}2 can have a crystalline structure, such as nanocrystalline ZnO. FIG. 5 provides a diagrammatic illustration of the additional TCO layer TCO_{—}2 formed on the TCO layer of FIG. 4. Notably, the additional TCO layer is formed on the peaks and in the valley portions in which the coating resides. All or substantially all of the TCO layer of FIG. 4 may be covered by this additional TCO layer TCO_{—}2.

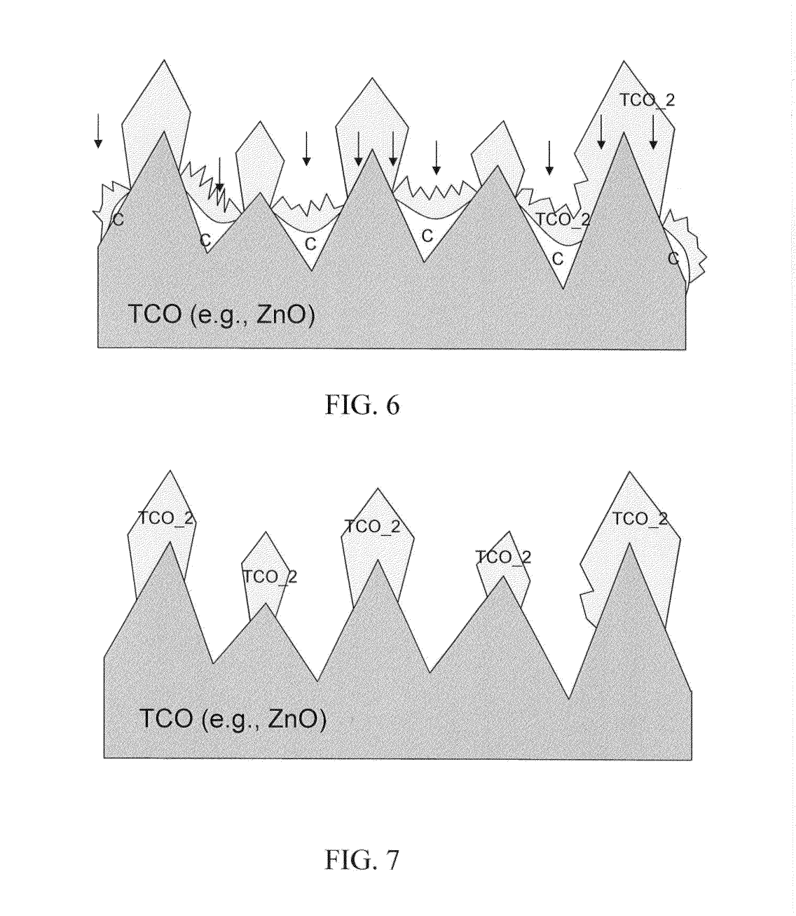

Method 300 can also include a process S310 of selectively removing portions of the additional TCO layer TCO_{—}2. Such selective removing S310 can also include removing the coating C. The selective removing of S310 can be performed by applying water or a solvent, such as acetone (represented in FIG. 6 by down-going arrows). Optionally, depending upon the type of coating used, thermal stress may be used in S310 to enhance or better ensure removal of the coating. Another optional process to enhance or ensure removal of the coating is sonication. FIG. 6 provides an example of the process to selectively remove or lift-off portions of the additional TCO layer and to remove (e.g., remove completely) the coating C, and FIG. 7 illustrates a result of S310's selective removal or lift-off of portions of the additional TCO layer TCO_{—}2 and the coating C. Thus, as illustrated in FIG. 7, portions of the additional TCO layer TCO_{—}2 remain only on peak portions of the surface topography. Further, the heights of the peaks are now taller with the remaining TCO_{—}2 portions, thereby modifying the topography of the initial TCO layer to make it rougher.

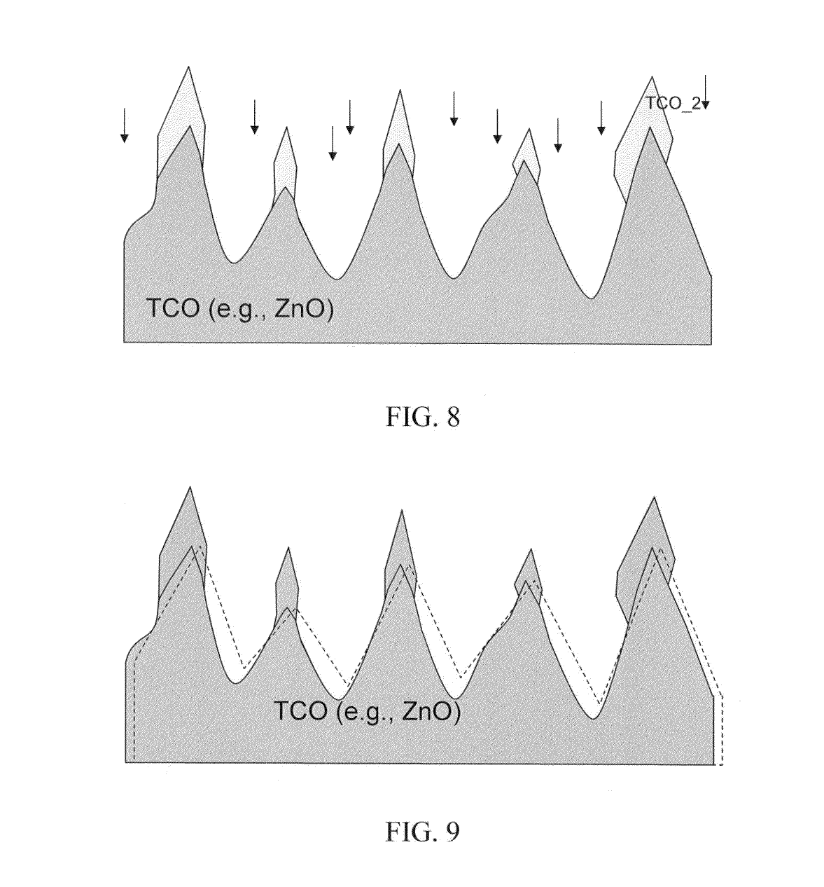

Some or all of the remaining TCO_{—}2 portions on the peaks can include facets that face downward. Such angles can cause unwanted reflections of light entering or within the layer. Thus, method 300 can also include a process S312 of further modifying the topography of the TCO layer. The process of S312 can include modifying the remaining portions of the additional TCO layer TCO_{—}2 and portions of the first TCO layer exposed from the remaining additional TCO layer portions. More specifically, the remaining portions of the additional TCO layer TCO_{—}2 can be modified to reduce the remaining portions of the TCO layer TCO_{—}2 to remove or reduce in angle the downward-facing facets, and the exposed portions of the first TCO layer can be modified to increase the depth of the valleys for the first TCO layer. Thus, S312 can make even rougher the surface topography. Further modification in S312 can be performed by a surface treatment, for example, an Argon surface treatment. An alternative to Argon as a surface treatment is a relatively weak acid, such as hydrochloric acid. FIG. 8 represents an example of the modification in S312 of method 300. Further modification in S312 can also smooth the surface of the sides of the peaks and valley portions.

FIG. 9 illustrates a change from the initial surface topography (dashed lines) for method 300 to a resultant surface topography. Notably, both the peaks and valleys are increased according to method 300. For example, the feature sizes may be characterized as having “double” or “almost double” pyramid heights. Thus, method 300 modifies the surface topography to increase roughness, aspect ratio, and/or peak-to-valley heights. Non-limiting examples of ranges and amounts of lateral size (i.e., quasi-pitch or self-correlation length) of the resultant TCO surface can be as described above.

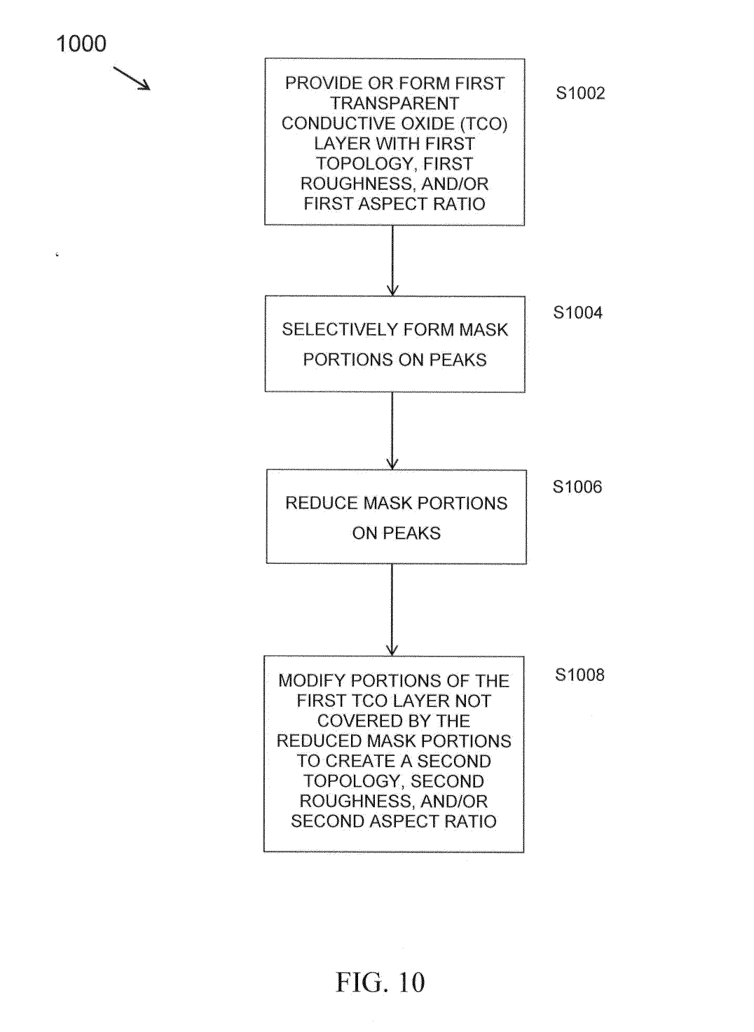

Turning to FIGS. 10-14, FIG. 10 represents a flow chart of a method 1000 according to embodiments of the present invention. Generally speaking, method 1000 can produce a TCO layer, such as ZnO, with a surface topography having an increased roughness, aspect ratio, or peak-to-valley heights of surface topography of a desired or predetermined roughness or aspect ratio or an amount of increase in aspect ratio relative to the initial (i.e., as-grown) aspect ratio state of such surface topography. Method 1000 may be referred to generally as a method to provide or fabricate a TCO layer having a surface topography with a desired surface roughness by selective etching the initial (e.g., as-grown) TCO layer along with masking (e.g., with micro-crystalline silicon (μc-Si)). Further, method 1000 can include, generally speaking, modifying a first pyramidal topography to create the second pyramidal topography by increasing respective depths of the valleys of the first pyramidal topography. Optionally, the heights of the pyramidal topography may not be increased or some heights may actually decrease slightly.

Method 1000 can be comprised of a step or process S1002 (which may involve multiple sub-steps or sub-processes), which includes providing or forming a transparent conductive oxide (TCO) layer, such as a ZnO layer. The TCO layer can be formed or otherwise provided by a LPCVD process, for instance. The TCO layer may be in the form of an as-grown ZnO layer, and such as-grown layer may have a surface topography in the form of randomized pyramidal structures with peaks of valleys of varying size, heights, and/or depths.

Method 1000 can also include a process S1004 of selectively forming mask portions MP on the peaks of the surface topography of the provided TCO layer. The mask portions MP can be formed of micro-crystalline silicon (μc-Si), for example, p-type, via a PECVD process. FIG. 11 illustrates an example of the mask portions MP formed on the peaks of the TCO layer. The mask portions MP may be formed only on the peaks or substantially only on the peaks (i.e., selectively formed) by diluting the PECVD process, for instance, using a relatively large amount of hydrogen, along with a low suitable low temperature and pressure (e.g., 0.5 mB-2 mB). Optionally, some gradient of masking portions may extend from the peaks down the side of the pyramids and may or may not reach corresponding valley bottoms.

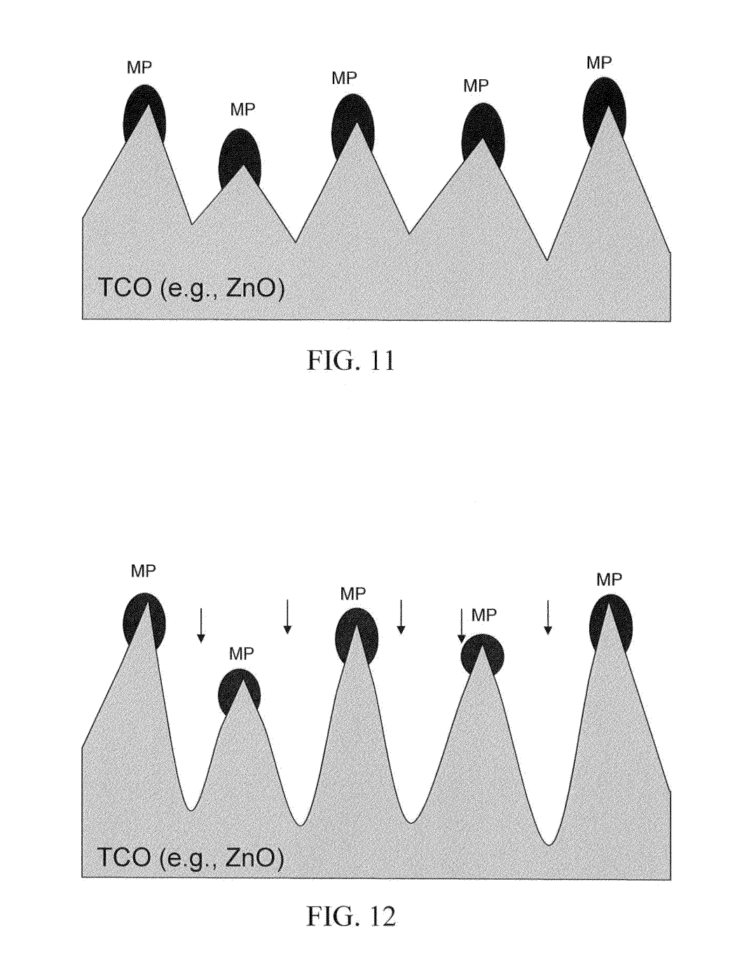

Method 1000 can also include a relatively short etching process S1006, for example, plasma etching using an SF6/O2 gas mixture, or an etching process using F or an F-containing gas, to reduce the masking portions. FIG. 12 illustrates an example of the reduced masking portions as compared to their form in FIG. 11. Such reducing of the masking portions can be helpful in a subsequent process of increasing the depth of the valleys in that it exposes additional portions of the TCO layer for the subsequent process.

Method 1000 can also include a process S1008 of modifying portions of the TCO layer not covered by the reduced mask portions to thereby modify the topography of the TCO layer. For example, S1008 can include an etching process (e.g., a wet etching process) to increase the depth of the valleys of the TCO layer and to not modify the peaks of the TCO layer. S1008 may also include a further etching process to reduce rough surfaces resulting from the first etching process. For example, the additional etch can be a sputter etch using Ar, for instance, to smooth the rough surfaces or surface texture after the wet etch process. Alternatively, the additional etch can be performed with a relatively weak acid, such as hydrochloric acid.

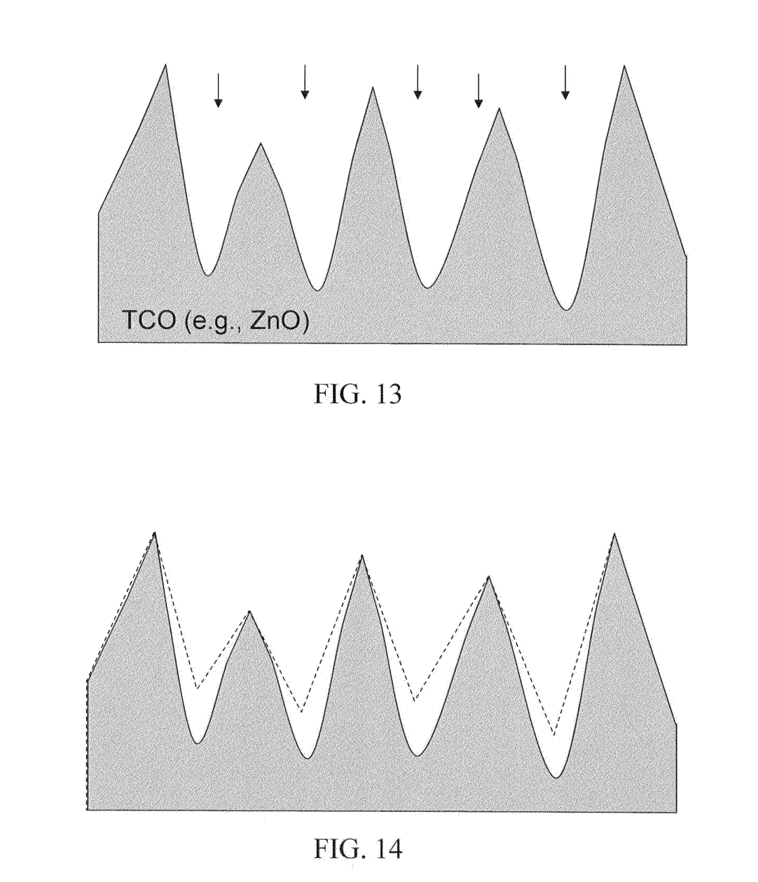

Method 1000 can optionally include a process of removing the masking portions. For example, the masking portions may be etched in an SF6/O2 treatment. FIG. 13 illustrates an example where the masking portions are removed.

FIG. 14 illustrates a change from the initial surface topography (dashed lines) for method 1000 versus a resultant surface topography. Notably, the peaks are not increased, but the depths of valleys are increased according to method 1000. The feature sizes may be characterized as having “double” or “almost double” pyramid heights. Thus, method 1000 modifies the surface topography to increase roughness, aspect ratio, and/or peak-to-valley heights. Non-limiting examples of ranges and amounts of lateral size (i.e., quasi-pitch or self-correlation length) of the resultant TCO surface can be as described above.

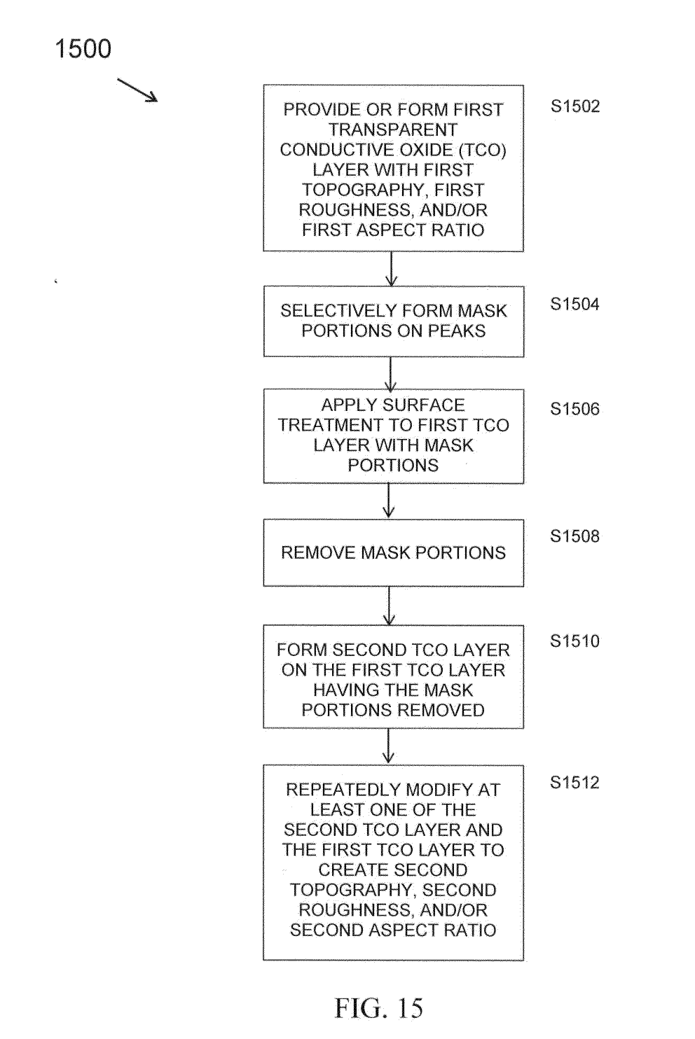

Turning to FIGS. 15-20, FIG. 15 represents a flow chart of a method 1500 according to embodiments of the present invention. Generally speaking, method 1500 can produce a TCO layer, such as ZnO, with a surface topography having an increased roughness, aspect ratio, or peak-to-valley heights of surface topography of a desired or predetermined roughness and/or aspect ratio or an amount of increase in aspect ratio relative to the as-grown aspect ratio with respect to an initial (e.g., as-grown) state of such surface topography. Method 1500 may be referred to generally as a method to provide or fabricate a TCO layer having a surface topography with a desired surface roughness by selective B₂H₆ (i.e., diborane) exposure with masking by micro-crystalline silicon (μc-Si), followed by etching (multiple times). Optionally, the etching can be performed (i.e., repeated) from two to ten times, for example, until texture height is almost doubled. Further, method 1500 can include, generally speaking, modifying a first pyramidal topography to create the second pyramidal topography by increasing both of respective heights of the peaks and respective depths of the valleys of the first pyramidal topography.

Method 1500 can be comprised of a step or process S1502 (which may involve multiple sub-steps or sub-processes), which includes providing or forming a transparent conductive oxide (TCO) layer, such as a ZnO layer. The TCO layer can be formed or otherwise provided by a LPCVD process, for instance. The TCO layer may be in the form of an as-grown ZnO layer, and such as-grown layer may have a surface topography in the form of randomized pyramidal structures with peaks of valleys of varying size, heights, and/or depths.

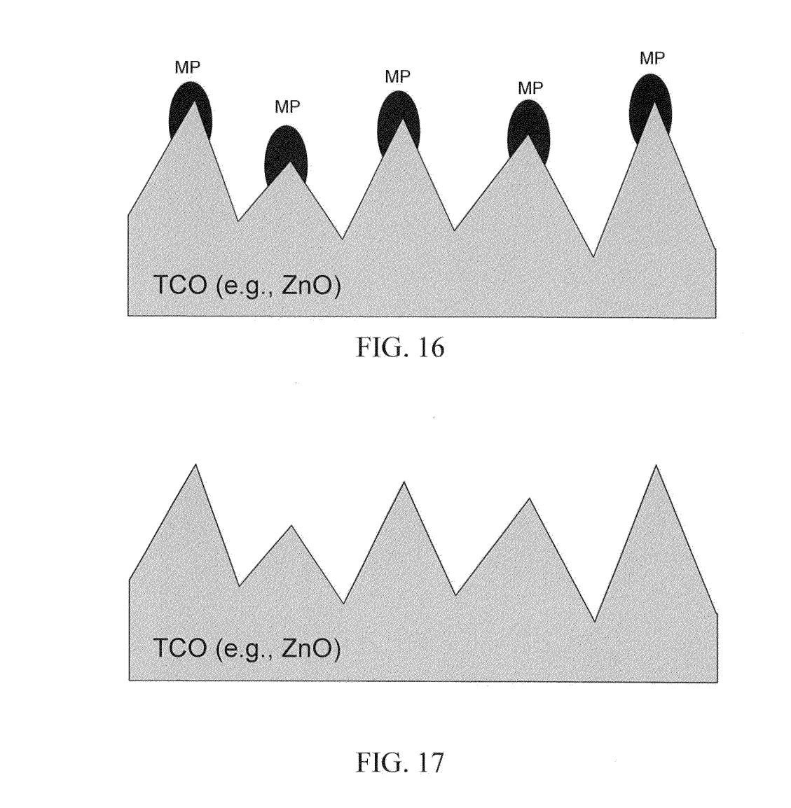

Method 1500 can also include a process S1504 of selectively forming mask portions MP on the peaks of the surface topography of the provided TCO layer. The mask portions MP can be formed of micro-crystalline silicon (μc-Si), for example, p-type, via a PECVD process. FIG. 16 illustrates an example of the mask portions MP formed on the peaks of the TCO layer. The mask portions MP may be formed only on the peaks or substantially only on the peaks (i.e., selectively formed) by diluting the PECVD process, for instance, by using a relatively large amount of hydrogen, along with a low suitable low temperature and pressure (e.g., 0.5 mB-2 mB). Optionally, some gradient of masking portions may extend from the peaks down the side of the pyramids and may or may not reach corresponding valley bottoms.

Method 1500 can also include a process S1506 of applying a surface treatment to the TCO layer having the mask portions. Such surface treatment can include exposure to B₂H₆ to form, for example, a breaking layer (not expressly shown). Notably in S1506, since the peaks of the TCO layer are covered by masking portions MP, such peaks are not exposed to B₂H₆ and therefore are not doped therewith. Method 1500 can also include S1508 of removing the masking portions MP, for example, via an etching process using SF6O2, for instance. FIG. 17 provides an illustration of an example of the resultant TCO layer exposed to B₂H₆ in S1506 and with the masking portions MP removed in S1508.

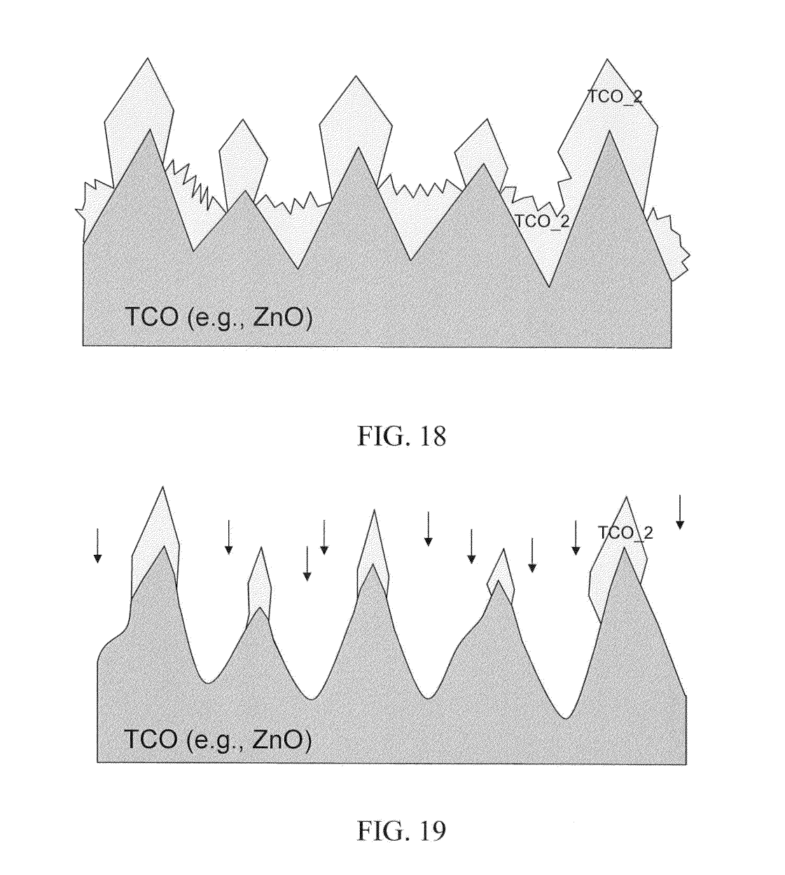

Method 1500 can also include a process S1510 of forming a transparent TCO layer or layer portions TCO_{—}2 on the initial TCO layer subjected to the treatments in S1504-S1508. For example, process S1510 can form another ZnO layer TCO_{—}2 via deposition (e.g., via LPCVD) on an initial, as-grown ZnO layer subjected to processes in S1504-S1508. The second TCO layer TCO_{—}2 can have a crystalline structure, such as nanocrystalline ZnO. FIG. 18 provides a diagrammatic illustration of the additional TCO layer TCO_{—}2 formed on the TCO layer of FIG. 17. Notably, the additional TCO layer TCO_{—}2 is formed on the peaks and in the valley portions. All or substantially all of the TCO layer of FIG. 17 may be covered by this additional TCO layer TCO_{—}2.

Method 1500 can further include a process S1512 of repeatedly modifying at least one of the additional TCO layer and the initial TCO layer to create a modified topography. Such modification can include an etching process, for instance an Ar surface treatment, which can be repeated multiple times. For instance, the etching process may be performed two to three times. FIG. 19 illustrates diagrammatically the etching process.

FIG. 20 illustrates a change from the initial surface topography (dashed lines) for method 1500 to a resultant surface topography. Notably, the heights of the peaks and depths of valleys are increased according to method 1500. The feature sizes may be characterized as having “double” or “almost double” pyramid heights. Thus, method 1500 modifies the surface topography to increase roughness, aspect ratio, and/or peak-to-valley heights. Non-limiting examples of ranges and amounts of lateral size (i.e., quasi-pitch or self-correlation length) of the resultant TCO surface can be as described above.

Incidentally, though the figures are discussed herein with respect to a randomly patternized surface topography of a TCO film (e.g., ZnO), embodiments of the present invention are not so limited, and the present invention also can include “regularly” patternized surface topography, such as periodic and relatively flat topographies. Thus, in the case of a periodic TCO topography, embodiments of the present invention modify such periodic topography to increase roughness, aspect ratio, or peak-to-valley heights. In the case of relatively flat topography, embodiments of the present invention can form or otherwise modify the TCO from its relatively flat form to a first form with a first topography with peaks and valleys (pyramidal or otherwise), and then modify this topography to increase roughness, aspect ratio, and/or peak-to-valley heights. Or, embodiments of the present invention can modify the relatively flat topography to create a resultant topography with a desired or predetermined roughness, aspect ratio, or peak-to-valley height.

Processes or steps according to embodiments of the present invention can be realized in a TCO deposition system, for example, equipped with 2 process modules (PM1 and PM2) and Load/Unload Locks (LL). Other, comparable systems may be used without deviating from the invention. The number of PM shall not be limiting, it may be less or more. Further, steps addressing handling, moving, heat-up times, etc. may be system-specific and thus may be realized differently; however this does not affect general surface treatment aspect of the invention. Moreover, embodiments of the invention also may be implemented as an inline process with a treatment curtain.

As noted above, embodiments of the invention may be implemented as a multi-chamber system. For example, if the deposition system comprises more than two chambers, the treatment subsystem can be placed between any of the deposition chambers. Depending on the number of treatment subsystems and depending on their positions, it is possible to achieve discrete thickness ratios between TCO layers. Additionally, tuning the treatment and purging times allows controlling the thickness of the deposited TCO layers. Additionally, in a system used for LPCVD comprising e.g., two deposition chambers, it is possible to add an additional subsystem between the first and the second deposition chamber.

Entire processes or portions thereof according to embodiments of the invention may also be implemented as separate machines. For example, a treatment can be performed as last step in the first machine, then the substrate is exposed to air and then another process, such as deposition of a second TCO layer as described herein, is continued within a second machine.

Having now described embodiments of the present invention, it should be apparent to those skilled in the art that the foregoing is merely illustrative and not limiting, having been presented by way of example only. Thus, although particular configurations have been discussed and illustrated herein, other configurations can also be employed. Numerous modifications and other embodiments (e.g., combinations, rearrangements, etc.) are enabled by the present disclosure and are within the scope of one of ordinary skill in the art, and are contemplated as falling within the scope of the disclosed subject matter and any equivalents thereto. Features of the disclosed embodiments can be combined, rearranged, omitted, etc., within the scope of the invention to produce additional embodiments. Furthermore, certain features may sometimes be used to advantage without a corresponding use of other features. Accordingly, Applicant intends to embrace all such alternatives, modifications, equivalents, and variations that are within the spirit and scope of the present invention.

1. A method of fabricating a transparent conductive oxide (TCO) layer, comprising:
providing a first transparent ZnO layer, the first ZnO layer being an as-grown, randomly pyramidal textured ZnO layer having a first pyramidal topography with a first roughness and a first aspect ratio; and
modifying the first pyramidal topography to create a second pyramidal topography with a second roughness greater than the first roughness and with a second aspect ratio greater than the first aspect ratio.

2. The method according to claim 1, wherein the second aspect ratio is greater by two than the first aspect ratio.

3. The method according to claim 1, wherein said modifying the first pyramidal topography to create the second pyramidal topography includes:
increasing at least one of respective heights of the peaks and respective depths of the valleys of the first pyramidal topography.

4. The method according to claim 3, wherein said modifying the first pyramidal topography to create the second pyramidal topography includes:
increasing both of the respective heights of the peaks and the respective depths of the valleys of the first pyramidal topography.

5. The method according to claim 4, wherein said increasing both respective heights of the peaks and respective depths of the valleys includes:
applying a first surface treatment to the first pyramidal topography of the first ZnO layer;
applying a coating to the valleys of the first pyramidal topography of the first ZnO layer;
forming a second transparent ZnO layer on the first ZnO layer having the first surface treatment and the coating in the valleys;
selectively removing portions of the second transparent ZnO layer formed in the valleys, said selective removing also removing the coating; and
modifying the remaining portions of the second transparent ZnO layer and portions of the first ZnO layer exposed from the remaining second transparent ZnO portions to create the second pyramidal topography.

6. The method according to claim 4, wherein said increasing both respective heights of the peaks and respective depths of the valleys includes:
selectively forming mask portions that cover the peaks of the first pyramidal topography of the first ZnO layer;
applying a first surface treatment to the first ZnO layer with the selectively formed mask portions covering the peaks;
after said applying the first surface treatment, removing the mask portions;
forming a second transparent ZnO layer on the first ZnO layer having the mask portions removed; and
repeatedly modifying at least one of the second transparent ZnO layer and the first transparent ZnO layer to create the second pyramidal topography.

7. The method according to claim 3, wherein said modifying the first pyramidal topography to create the second pyramidal topography includes:
increasing only the respective depths of the valleys of the first pyramidal topography, said increasing only the respective depths of the valleys including:
selectively forming mask portions that cover the peaks of the first pyramidal topography of the first ZnO layer;
reducing the mask portions covering the peaks; and
modifying portions of the first ZnO layer not covered by the reduced mask portions to create the second pyramidal topography.

8. A method of fabricating a precursor for a thin-film silicon solar cell, comprising:
providing, in a processing chamber of fabrication equipment, a thin-film silicon layer;
depositing, using the processing chamber of the fabrication equipment, a first transparent conductive ZnO layer on the thin-film silicon layer to form an Si—ZnO interface, the first ZnO layer being an as-grown, randomly pyramidal textured ZnO layer having a first pyramidal topography with a first roughness; and
modifying, using the fabrication equipment, the first pyramidal topography of the first ZnO layer to create a ZnO layer having second pyramidal topography with a second roughness greater than the first roughness, said modifying the first pyramidal topography to create the second pyramidal topography including increasing at least one of respective heights of the peaks and respective depths of the valleys of the first pyramidal topography.

9. The method according to claim 8, wherein said modifying the first pyramidal topography to create the second pyramidal topography includes increasing both of the respective heights of the peaks and the respective depths of the valleys of the first pyramidal topography, said increasing respective heights of the peaks and respective depths of the valleys including:
applying a first surface treatment to the first pyramidal topography of the first ZnO layer;
applying a coating to the valleys of the first pyramidal topography of the first ZnO layer;
forming a second transparent ZnO layer on the first ZnO layer having the first surface treatment and the coating in the valleys;
selectively removing portions of the second transparent ZnO layer formed in the valleys, said selective removing also removing the coating; and
applying a second surface treatment to remaining portions of the second transparent ZnO layer and portions of the first ZnO layer exposed from the remaining second transparent ZnO portions to create the second pyramidal topography.

10. The method according to claim 8, wherein said modifying the first pyramidal topography to create the second pyramidal topography includes increasing both of the respective heights of the peaks and the respective depths of the valleys of the first pyramidal topography, said increasing respective heights of the peaks and respective depths of the valleys including:
selectively forming mask portions that cover the peaks of the first pyramidal topography of the first ZnO layer by applying a first surface treatment;
applying a second surface treatment to the first ZnO layer with the selectively formed mask portions covering the peaks;
removing the mask portions after said applying the second surface treatment;
forming a second transparent ZnO layer on the first ZnO layer having the mask portions removed; and
creating the second pyramidal topography by repeatedly applying a third surface treatment.

11. The method according to claim 8, wherein said modifying the first pyramidal topography to create the second pyramidal topography includes increasing only the respective depths of the valleys of the first pyramidal topography, said increasing only the respective depths of the valleys including:
applying a first surface treatment to the first pyramidal topography of the first ZnO layer to selectively form mask portions that cover the peaks of the first pyramidal topography of the first ZnO layer;
reducing the mask portions covering the peaks; and
creating the second pyramidal topography by applying a second surface treatment.

12. The method according to claim 8, wherein increase of the respective heights to the second pyramidal topography increases a statistical aspect ratio of the peaks and valleys by a degree of two or approximately two.

13. A system for fabricating a transparent conductive oxide (TCO) layer, comprising:
an apparatus configured to:
provide a first TCO layer, the first TCO layer having an as-grown, randomly textured topography with a first roughness and a first aspect ratio; and
modify the as-grown topography to create a second topography with a second roughness greater than the first roughness and with a second aspect ratio greater than the first aspect ratio.

14. The system according to claim 13, wherein the second aspect ratio is greater by two than the first aspect ratio.

15. The system according to claim 13, wherein said modifying the first topography to create the second topography includes:
increasing at least one of respective heights of peaks and respective depths of valleys of the first topography.

16. The system according to claim 15, wherein said modifying the first topography to create the second topography includes:
increasing both of the respective heights of the peaks and the respective depths of the valleys of the first topography.

17. The system according to claim 16, wherein said increasing respective heights of the peaks and respective depths of the valleys includes:
applying a first surface treatment to the first topography of the first TCO layer;
applying a coating to the valleys of the first topography of the first TCO layer;
forming a second TCO layer on the first TCO layer having the first surface treatment and the coating in the valleys;
selectively removing portions of the second TCO layer formed in the valleys, said selective removing also removing the coating; and
modifying the remaining portions of the second TCO layer and portions of the first TCO layer exposed from the remaining second TCO layer portions to create the second topography.

18. The system according to claim 16, wherein said increasing respective heights of the peaks and respective depths of the valleys includes:
selectively forming mask portions that cover the peaks of the first topography of the first TCO layer;
applying a first surface treatment to the first TCO layer with the selectively formed mask portions covering the peaks;
after said applying the first surface treatment, removing the mask portions;
forming a second TCO layer on the first TCO layer having the mask portions removed; and
repeatedly modifying at least one of the second TCO layer and the first TCO layer to create the second topography.

19. The system according to claim 15, wherein said modifying the first topography to create the second topography includes:
increasing only the respective depths of the valleys of the first topography, said increasing only the respective depths of the valleys including:
selectively forming mask portions that cover the peaks of the first topography of the first TCO layer;
reducing the mask portions covering the peaks; and
modifying portions of the first TCO layer not covered by the reduced mask portions to create the second topography.

20. The system according to claim 15, wherein the first TCO layer is a transparent conductive ZnO layer.
